(19) United States
(12) Patent Application Publication
(10) Pub. No.: US 2020/0043864 A1
(43) Pub. Date: Feb. 6, 2020

(54) MODULE

(71) Applicant: Murata Manufacturing Co., Ltd., Kyoto (JP)

(72) Inventors: Yoshihito OTSUBO, Kyoto (JP); Motohiko KUSUNOKI, Kyoto (JP)

(21) Appl. No.: 16/524,444

(22) Filed: Jul. 29, 2019

(30) Foreign Application Priority Data
Aug. 3, 2018 (JP) 2018-146858
May 13, 2019 (JP) 2019-090885

(51) Int. Cl. H01L 23/552; H01L 23/00; H01L 23/498

(52) U.S. Cl. CPC H01L 23/552; H01L 2924/14215; H01L 23/49822; H01L 24/49

(57) ABSTRACT

A module includes a substrate having a main surface, a first component mounted on the main surface, and two or more wires bonded to the main surface so as to straddle the first component. Each of the two or more wires has a first end and a second end. When attention is paid to two wires adjacent to each other out of the two or more wires, a distance between the first ends of the two wires is shorter than a distance between the second ends of the two wires.

This application claims priority from Japanese Patent Application No. 2018-146858 filed on Aug. 3, 2018, and claims priority from Japanese Patent Application No. 2019-090885 filed on May 13, 2019. The contents of these applications are incorporated herein by reference in their entireties.

### BACKGROUND

The present disclosure relates to a module.

In an electronic module in which a die (electronic component) is enclosed in a mold compound (sealing resin), an electronic module having a structure in which a wire bond spring is used as a shield for shielding electromagnetic waves, is described in Japanese Patent No. 5276169.

In the structure described in Japanese Patent No. 5276169, the wire bond spring is only formed on an outer periphery of a resin sealed module, and there is a problem that the shield performance is insufficient.

### BRIEF SUMMARY

Accordingly, the present disclosure provides a module having improved shield performance.

A module according to embodiments of the present disclosure includes a substrate having a main surface, a first component mounted on the main surface, and two or more wires bonded to the main surface so as to straddle the first component, in which each of the two or more wires has a first end and a second end, and when attention is paid to two wires adjacent to each other out of the two or more wires, a distance between the first ends of the two wires is shorter than a distance between the second ends of the two wires.

According to the present disclosure, since two or more wires are bonded to the main surface so as to straddle the first component, it is possible to shield the first component. In particular, the wires are densely arrayed in a portion where the first ends are lined up, and it is possible to selectively and particularly shield the wires. Therefore, the module having improved shield performance can be provided.

Other features, elements, characteristics and advantages of the present disclosure will become more apparent from the following detailed description of embodiments of the present disclosure with reference to the attached drawings.

### BRIEF DESCRIPTION OF THE SEVERAL VIEWS OF THE DRAWINGS

FIG. 1 is a first perspective view of a module according to a first embodiment of the present disclosure;

FIG. 2 is a second perspective view of the module according to the first embodiment of the present disclosure;

FIG. 3 is a perspective plan view of the module according to the first embodiment of the present disclosure;

FIG. 4 is a sectional view taken along a line IV-IV in FIG. 3;

FIG. 5 is a perspective plan view exactly illustrating a region of the module according to the first embodiment of the present disclosure;

FIG. 6 is a perspective plan view of a module according to a second embodiment of the present disclosure;

FIG. 7 is a perspective plan view of a first variation on the module according to the second embodiment of the present disclosure;

FIG. 8 is a perspective plan view of a second variation on the module according to the second embodiment of the present disclosure;

FIG. 9 is a perspective plan view of a module according to a third embodiment of the present disclosure;

FIG. 10 is a perspective plan view exactly illustrating a region of the module according to the third embodiment of the present disclosure;

FIG. 11 is a perspective plan view of a variation on the module according to the third embodiment of the present disclosure;

FIG. 12 is a perspective plan view of a module according to a fourth embodiment of the present disclosure;

FIG. 13 is a perspective plan view exactly illustrating a region of the module according to the fourth embodiment of the present disclosure;

FIG. 14 is a perspective plan view of a module according to a fifth embodiment of the present disclosure;

FIG. 15 is a perspective plan view exactly illustrating a region of the module according to the fifth embodiment of the present disclosure;

FIG. 16 is a perspective plan view of a variation on the module according to the fifth embodiment of the present disclosure;

FIG. 17 is a perspective plan view of a module according to a sixth embodiment of the present disclosure;

FIG. 18 is a perspective plan view exactly illustrating a region of the module according to the sixth embodiment of the present disclosure; and

FIG. 19 is a perspective plan view of a variation on the module according to the sixth embodiment of the present disclosure.

### DETAILED DESCRIPTION

The dimension ratio shown in the drawings does not always exactly represent a real ratio, and the dimension ratio may be exaggerated for convenience of explanation in some cases. In the description that follows, reference to the concept of upper or lower may not necessarily mean absolute upper or lower, but may mean relative upper or lower in an illustrated posture in some cases.

### First Embodiment

### Configuration

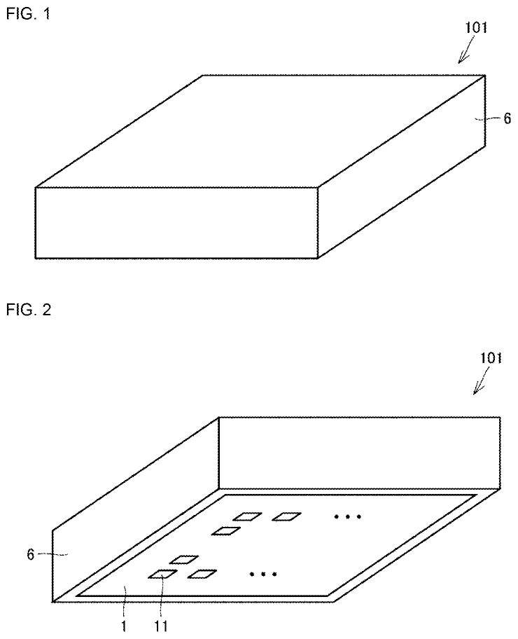

A module according to a first embodiment of the present disclosure will be described below with reference to FIG. 1 to FIG. 4. The module described herein may be a module with built-in components or a module with mounted components.

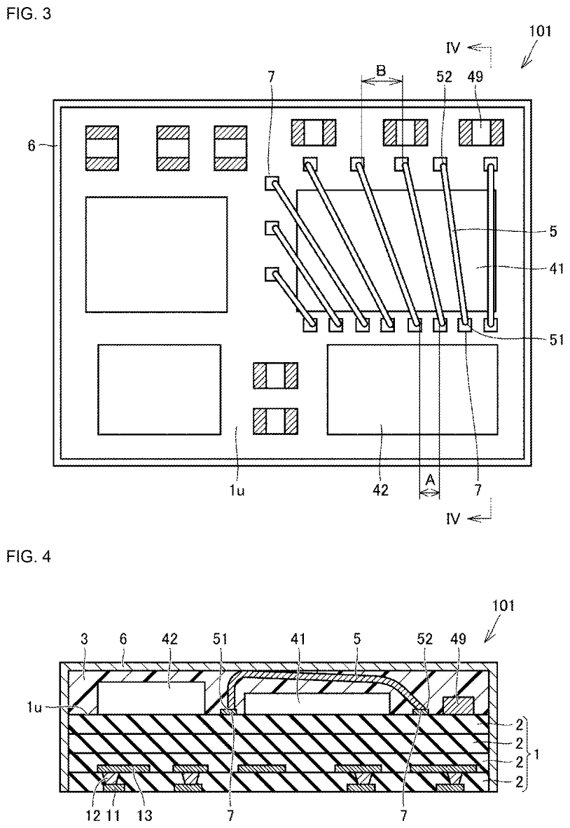

FIG. 1 illustrates an appearance of a module 101 according to the present embodiment. An upper surface and a side surface of the module 101 are covered with a shield film 6. FIG. 2 illustrates the module 101 when viewed from an angle at a lower side in FIG. 1. A lower surface of the module 101 is not covered with the shield film 6, and a substrate 1 is exposed. One or more external connection electrodes 11 are provided on a lower surface of the substrate 1. The number, the size and the arrangement of the external connection electrodes 11 illustrated in FIG. 2 are merely examples. The substrate 1 may be provided with a wiring on a surface or inside thereof. The substrate 1 may be a resin substrate or a ceramic substrate. The substrate 1 may be a multilayer substrate. A perspective plan view of the module 101 is illustrated in FIG. 3. FIG. 3 corresponds to a case of viewing from the top a state in which an upper surface of the shield film 6 of the module 101 is removed and a sealing resin 3 is removed. A first component 41 is mounted on a main surface 1u of the substrate 1. The first component 41 may be, for example, an integrated circuit (IC). More specifically, the first component 41 may be, for example, a low noise amplifier (LNA). A plurality of pad electrodes 7 is arranged on the main surface 1u. A sectional view taken along a line IV-IV in FIG. 3 is illustrated in FIG. 4.

The module 101 in this embodiment includes the substrate 1 having the main surface 1u, the first component 41 mounted on the main surface 1u, and two or more wires 5 bonded to the main surface 1u so as to straddle the first component 41. Each of the two or more wires 5 has a first end 51 and a second end 52. The first end 51 and the second end 52 are connected to any one of the pad electrodes 7, respectively. Here, “the first end” is a start point of bonding, and “the second end” is an end point of bonding. When attention is paid to two wires adjacent to each other out of the two or more wires 5, a distance A between the first ends 51 of the two wires is shorter than a distance B between the second ends 52 of the two wires. This can be achieved by setting the start point side as the first end and the end point side as the second end, as described above. That is, since the first end is the start point of bonding, when the first end is connected to the pad electrode 7, the wire 5 can be pulled up perpendicularly to the main surface 1u. Therefore, at this point, there is almost no risk of contact between the wire 5 and the first component 41. Accordingly, with respect to the first end, the wire 5 and the first component 41 can be arranged in close proximity to each other. On the other hand, since the second end is the end point of bonding and it is difficult to perpendicularly form the wire 5 toward the main surface 1u, it is necessary to separate the wire 5 from the first component 41 as compared with the first end side. In FIG. 4, the first end 51 is located close to the first component 41, whereas the second end 52 is away from the first component 41 due to such reasons. In this embodiment, a portion where the necessity of shield is higher is used as the first end of bonding.

As illustrated in FIG. 4, a conductor via 12 is electrically connected to the external connection electrode 11 provided on the lower surface of the substrate 1. Inside the substrate 1, an internal conductor pattern 13 is arranged. The conductor via 12 electrically connects the external connection electrode 11 and the internal conductor pattern 13 to each other so as to penetrate through an insulating layer 2. The positions, sizes and arrangements of the external connection electrode 11, the conductor via 12 and the internal conductor pattern 13 illustrated here are merely illustrated by way of example, and are not limited thereto.

In the example illustrated in FIG. 3 and FIG. 4, in addition to the first component 41, a second component 42 and a chip component 49 are mounted on the main surface 1u. The second component 42 may, for example, be an IC. Here, the chip component 49 is a capacitor, but the type of chip component is not limited to this. The chip component may be, for example, a filter or a resistor. The positions, sizes and arrangements of the various components mounted on the main surface 1u are merely shown by way of example, and are not limited thereto.

### Operation/Effects

In this embodiment, since two or more wires 5 bonded to the main surface 1u are provided so as to straddle the first component 41, the first component 41 can be shielded by these wires 5.

Further, in this embodiment, when attention is paid to two wires adjacent to each other out of the two or more wires 5, since the distance A between the first ends 51 of the two wires is shorter than the distance B between the second ends 52 of the two wires, the wires 5 are densely arrayed at a portion where the first ends 51 are lined up, so that it is possible to selectively and particularly shield the portion. Therefore, a module having improved shield performance can be realized.

As described in this embodiment, the module 101 can include the shield film 6 arranged so as to cover the first component 41 and the two or more wires 5 spaced apart from the main surface 1u. FIG. 4 illustrates a state in which the shield film 6 is spaced apart from the main surface 1u. By adopting this configuration, a shield effect by the shield film 6 can also be obtained. As illustrated in FIG. 4, a space inside the shield film 6 can be filled with the sealing resin 3. In other words, the module 101 can include the sealing resin 3 arranged so as to cover the first component 41 and the two or more wires 5. As described in this embodiment, when the module 101 also includes the second component 42, the module 101 can include the sealing resin 3 arranged to cover the first component 41, the second component 42, and the two or more wires 5.

As illustrated in FIG. 4, at least one of the two or more wires 5 can be in contact with the shield film 6. By adopting this configuration, the shield film 6 is connected to a ground of the substrate by the wire 5, so that the space surrounded by the shield film 6 can be efficiently shielded.

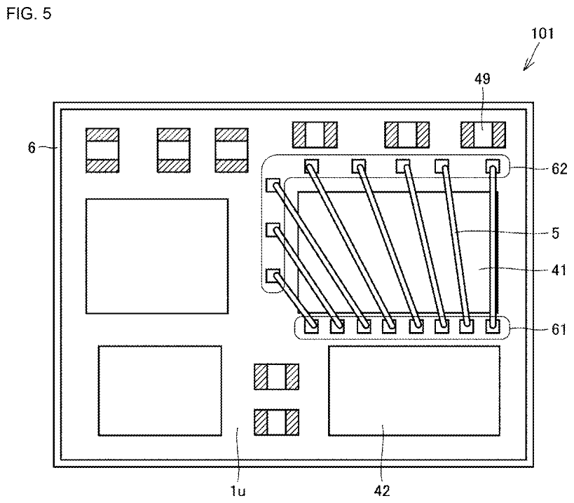

In the module 101 described in this embodiment, the arrangement of the ends of the wires 5 can be considered separately a first region 61 and a second region 62 as illustrated in FIG. 5. The first end 51 of the plurality of wires 5 is connected to the main surface 1u in the first region 61. The second end 52 of the plurality of wires 5 is connected to the main surface 1u in the second region 62.

In the example shown here, the first region 61 is arranged in a substantially linear manner along one side of the first component 41. The second region 62 is in a substantially L-shaped manner along two sides of the first component 41. The first region 61 is arranged between the first component 41 and the second component 42.

For example, it is assumed that the mutual electromagnetic interference between the first component 41 and the second component 42 is intended to be suppressed. As described in this embodiment, the module 101 can include the second component 42 mounted on the main surface 1u, that the main surface 1u have the first region 61 where the first ends 51 of the two or more wires 5 and the main surface 1u are connected, and that at least a part of the first region 61 be positioned between the first component 41 and the second component 42. By adopting this configuration, the first region 61 is arranged between the first component 41 and the second component 42, and the first ends 51 are densely arrayed in the first region 61, so that it is possible to selectively shield a portion between the first component 41 and the second component 42, and it is possible to reduce electromagnetic effects that may possibly occur between the first component 41 and the second component 42.

Note that the first ends 51 of the two or more wires 5 can be lined up on the same side. In the example described in this embodiment, when attention is paid to the set of the two or more wires 5, the first ends 51 are lined up on one side, and the second ends 52 are lined up on another side. The arrangement of the first ends 51 is denser than the arrangement of the second ends 52.

In a case where the first component 41 is the LNA, the receiving sensitivity can be improved. When the first component 41 is the LNA, an inductor for input matching of the LNA may be arranged in addition to the LNA as the first component 41. The inductor for input matching of the LNA can be shielded in the same manner.

### Second Embodiment

### Configuration

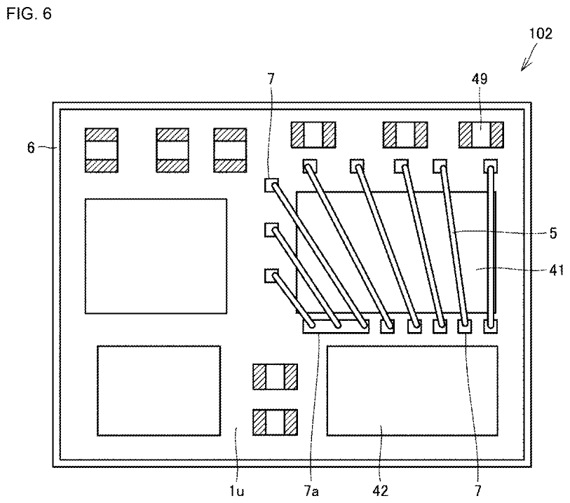

A module according to a second embodiment of the present disclosure will be described with reference to FIG. 6. FIG. 6 illustrates a module 102 according to the present embodiment in perspective plan view. The module 102 in this embodiment has the same basic configuration as that of the module 101 described in the first embodiment, but is different in the following points.

The module 102 includes a pad electrode 7a in addition to the pad electrode 7. The pad electrode 7 is connected to one first end 51 or one second end 52. The plurality of first ends 51 is connected to the pad electrode 7a.

In this embodiment, the integrating pad electrode 7a to which two or more of the first ends 51 are collectively connected is arranged in the first region 61.

### Operation/Effects

In this embodiment, since there is provided the integrating pad electrode 7a to which two or more of the first ends 51 are collectively connected, a portion using the integrating pad electrode 7a can be connected to the ground electrode of the substrate 1 by one via. In other words, when the pad electrodes are separate from each other, a via used for connection of the ground electrode of the substrate 1 is required for each of the separate pad electrodes, but by using an integrating pad electrode, it is possible to reduce the number of vias. In this embodiment, the same potential can be efficiently applied to the plurality of wires 5 in a collective manner.

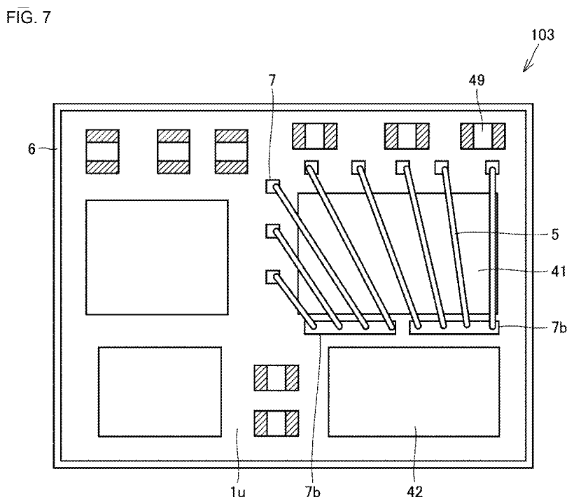

In the example illustrated in FIG. 6, the configuration in which the first region 61 includes one pad electrode 7a and the plurality of pad electrodes 7 is adopted, but is not limited thereto, and another combination may also be conceivable. For example, a module such as a module 103 illustrated in FIG. 7 may be adopted. In the module 103, the first region 61 includes a plurality of pad electrodes 7b, and the plurality of first ends 51 is connected to each of the pad electrodes 7b.

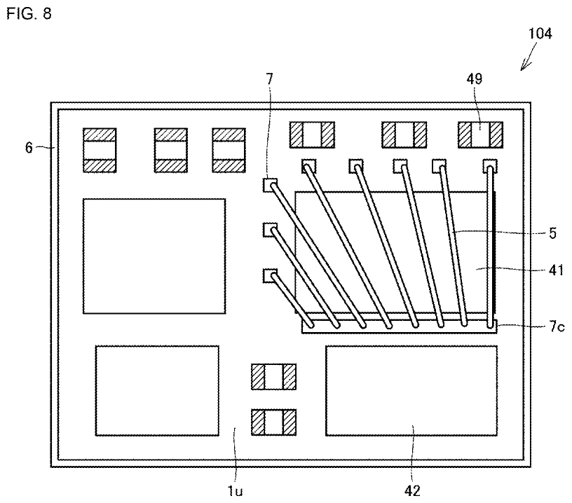

Furthermore, a module such as a module 104 illustrated in FIG. 8 may be adopted. In the module 104, the first region 61 includes one pad electrodes 7c, and all the first ends 51 connected to the main surface 1u in the first region 61 are connected to this one pad electrode 7c. In this manner, the connection with respect to the ground electrode of the substrate 1 can be made by one via. Further, the number of components can be reduced. In addition, when the common pad electrode 7c is arranged as described above, the ground potential can be easily and equally set for all the first ends 51 through the pad electrode 7c.

### Third Embodiment

### Configuration

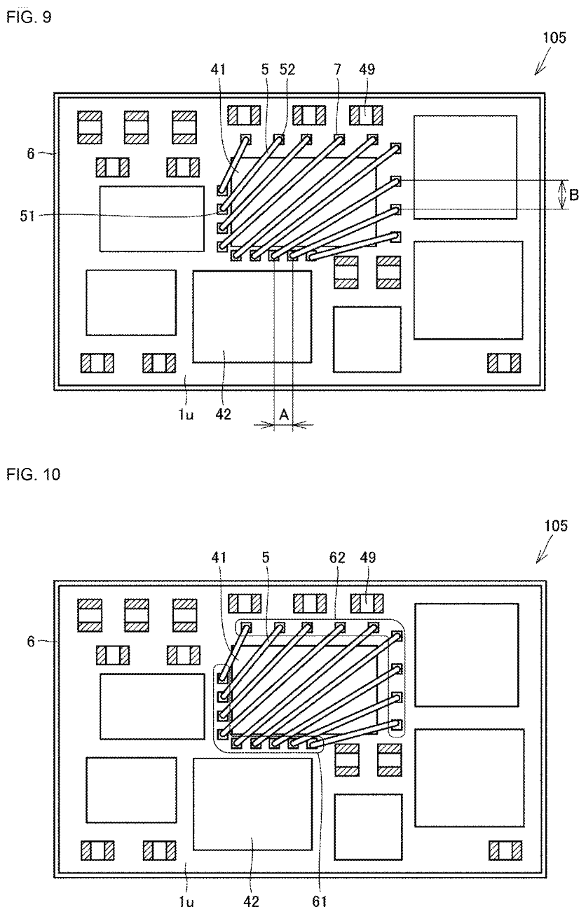

A module according to a third embodiment of the present disclosure will be described below with reference to FIG. 9 to FIG. 10. FIG. 9 illustrates a module 105 according to the present embodiment in perspective plan view. A region is clearly illustrated in FIG. 10. The module 105 in this embodiment has the same basic configuration as that of the module 101 described in the first embodiment, but is different in the following points.

In the module 105, the first component 41 is surrounded by at least a part of an aggregate of the first ends 51 and the second ends 52 of the two or more wires 5. That is, two or more wires 5 are arranged over the entire circumference of the first component 41 so as to straddle the first component 41. As illustrated in FIG. 10, the first region 61 in which the first ends 51 are arrayed may be substantially L-shaped. In the example illustrated in FIG. 10, the second region 62 in which the second ends 52 are arrayed is also substantially L-shaped. All of the wires 5 are not always the same length. In the example illustrated here, two or more wires 5 are densely arrayed on the first end side far from the shield film 6. Thus, the shielding performance can be improved even on the side far from the shield film 6.

### Operation/Effects

In this embodiment, the first component 41 is surrounded by the ends of the wires, so that the first component 41 can be sufficiently shielded, and further the first region 61 can be selectively and particularly shielded.

### Variation

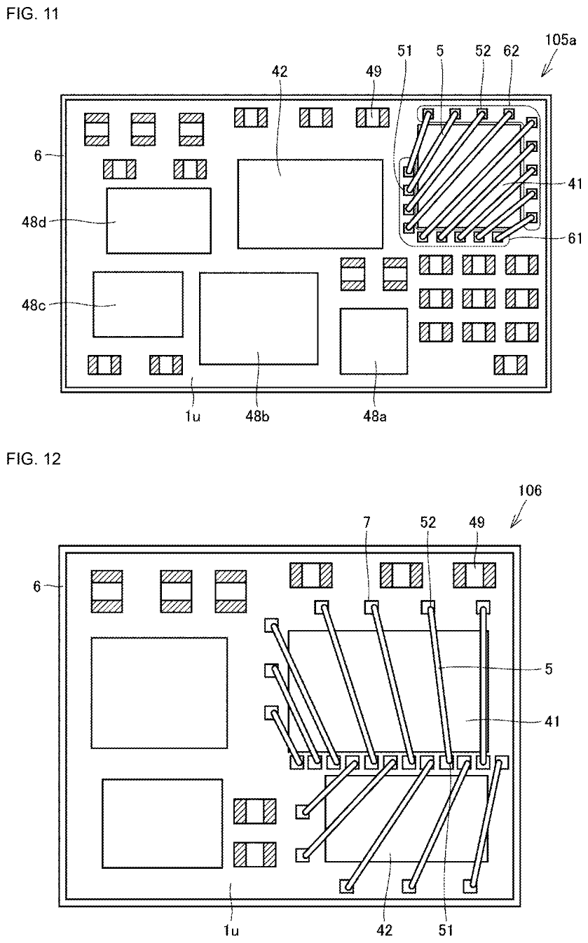

With reference to FIG. 11, a description will be given of a variation on the module according to the present embodiment. FIG. 11 illustrates a module 105a as the variation in perspective plan view. In the module 105a, the first component 41 is the LNA and the second component 42 is an Rx filter. In addition to the first component 41 and the second component 42, components 48a, 48b, 48c, and 48d are arranged on the main surface 1u of the substrate 1. The component 48a is an antenna switch (ANTSW). The component 48b is a Tx filter. The component 48c is a power amplifier (PA). The component 48d is a controller of the PA. The first component 41, which is the LNA, is surrounded by at least a part of the aggregate of the first ends 51 and the second ends 52 of the two or more wires 5. That is, two or more wires 5 are arranged so as to straddle the LNA over the entire circumference of the LNA. The first region 61 in which the first ends 51 are arrayed is substantially L-shaped along two sides of the first component 41 that is the LNA. The second region 62 in which the second ends 52 are arrayed is also substantially L-shaped along another two sides of the first component 41 which is the LNA. At least a part of the first region 61 is arranged to separate the first component 41, which is the LNA, from the second component 42, which is the Rx filter. Two or more wires 5 are densely arrayed on the first end 51 side. That is, the plurality of wires 5 straddling the LNA are densely arrayed on the first end 51 side that is the side of the second component 42 and the components 48a, 48b, 48c, and 48d. The plurality of wires 5 straddling the LNA is densely arrayed, in particular, on the first end 51 side that is a side on which the PA as a component for transmission, namely the component 48c is arranged. Therefore, in the module 105a, the effect of improving the receiving sensitivity is high.

### Fourth Embodiment

### Configuration

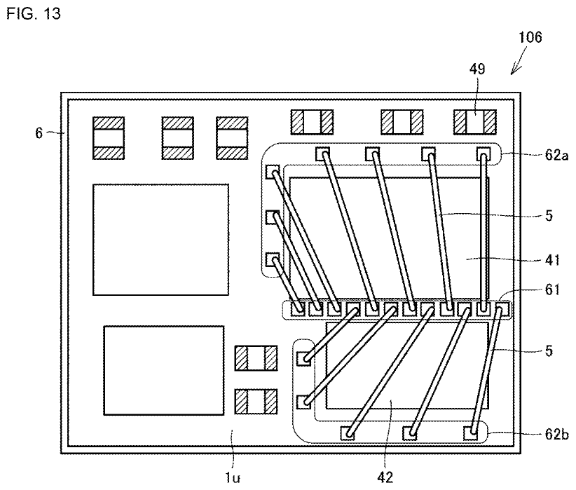

A module according to a fourth embodiment of the present disclosure will be described below with reference to FIG. 12 to FIG. 13. FIG. 12 illustrates a module 106 according to the present embodiment in perspective plan view. A region is clearly illustrated in FIG. 13.

The module 106 includes a substrate 1 having the main surface 1u, and a plurality of components mounted on the main surface 1u. Here, as an example of the plurality of components, the first component 41 and the second component 42 are illustrated. With respect to the plurality of components, two or more wires 5 bonded to the main surface 1u are arranged so as to straddle the components. That is, two or more wires 5 of a first group are arranged so as to straddle the first component 41, and two or more wires 5 of a second group are arranged so as to straddle the second component 42. As illustrated in FIG. 12, each of the two or more wires 5 has the first end 51 and the second end 52. As illustrated in FIG. 13, the main surface 1u has the common first region 61 in which the first ends 51 of the two or more wires 5 for the plurality of components are connected to the main surface 1u with concentration thereon. A distance between two first ends 51 adjacent to each other in the first region 61 is shorter than a distance between the second ends 52 adjacent to each other in a portion except the first region 61. In the example illustrated here, the second end 52 is connected to the main surface 1u in either of two second regions 62a and 62b. The second region 62a is arranged in a substantially L-shaped manner along two sides of the first component 41. The second region 62b is arranged in a substantially L-shaped manner along two sides of the second component 42. In the first region 61, the pad electrodes 7 are arrayed in a row in a substantially straight line. In the first region 61, the first ends 51 of the wires 5 straddling the first component 41 and the first ends 51 of the wires 5 straddling the second component 42 are alternately arranged.

### Operation/Effects

In this embodiment, since a structure in which two or more wires 5 straddle each of the plurality of components is configured, the shield can be formed individually on the plurality of components. Since the common first region 61 is provided, a large number of first ends 51 are concentrated in the first region 61, so that the shield can be more reliably achieved.

In the example illustrated here, the structure in which the wire 5 straddle the total two components of the first component 41 and the second component 42 has been exemplified, but the similar configuration may be considered for three or more components. Further, in addition to the plurality of components, a component that is not straddled by the wire 5 may be mounted on the main surface 1u of the substrate 1. Also in FIG. 12, for example, a component that is not straddled by any wire 5 is mounted on the left side in the figure. In FIG. 12, the chip component 49 is also mounted. The chip component 49 is illustrated by way of example but is optional.

### Fifth Embodiment

### Configuration

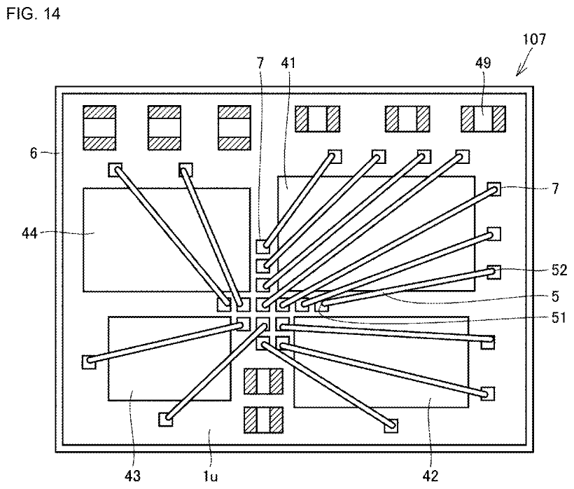

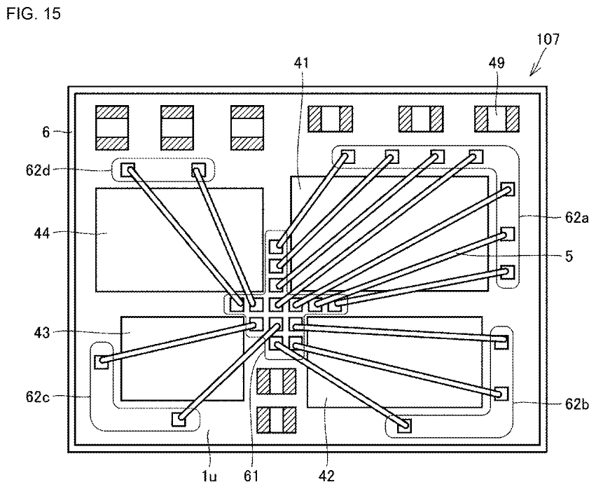

A module according to a fifth embodiment of the present disclosure will be described below with reference to FIG. 14 to FIG. 15. FIG. 14 illustrates a module 107 according to the present embodiment in perspective plan view. A region is clearly illustrated in FIG. 15.

In the module 107, four components are mounted on the main surface 1u of the substrate 1. That is, the first component 41, the second component 42, a third component 43 and a fourth component 44 are mounted on the main surface 1u. There is provided the common first region 61 in which the first ends 51 of the wires 5 with respect to these components are connected to the main surface 1u with concentration thereon, and the four components are arranged so as to contact the first region 61 at respective corner portions thereof. The first region 61 is located at a portion surrounded by the corner portions of the four components, and at the same time also extends to a space between two components. The first region 61 extends, for example, between the first component 41 and the second component 42. The first region 61 extends, for example, between the first component 41 and the fourth component 44. The second regions 62a, 62b, 62c and 62d are arranged along the sides of the respective components. The second regions 62a, 62b, 62c, and 62d correspond to the first component 41, the second component 42, the third component 43, and the fourth component 44, respectively.

### Operation/Effects

In this embodiment, the wires 5 are appropriately arranged, so that the shield can be made with respect to a plurality of components. In particular, in a region where the corner portions of the plurality of components are concentrated, the first region 61 is provided and the wires 5 are densely arranged, so that the influence of electromagnetic waves that may possibly occur in such a region can be selectively reduced on the region.

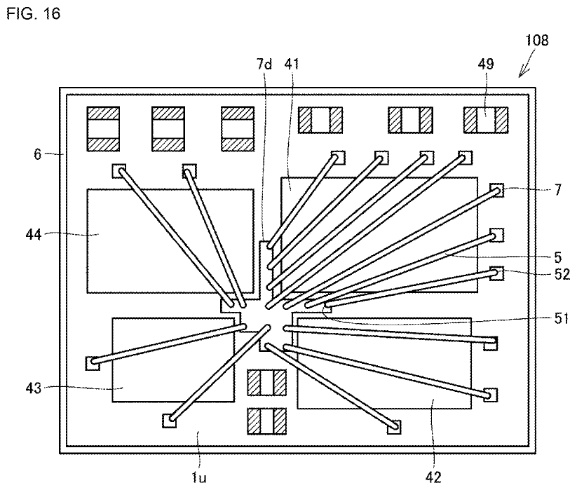

It should be noted that a configuration such as a module 108 illustrated in FIG. 16 may be adopted. In the module 108, an integrating pad electrode 7d is arranged in the first region 61 instead of arraying the individual pad electrodes. The first ends 51 of the plurality of wires 5 are connected to the pad electrode 7d.

### Sixth Embodiment

### Configuration

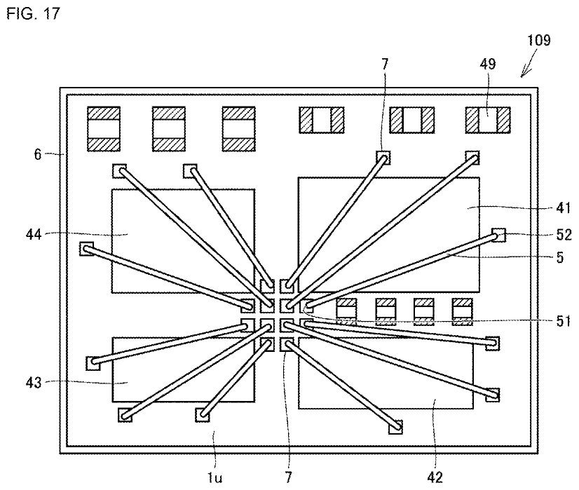

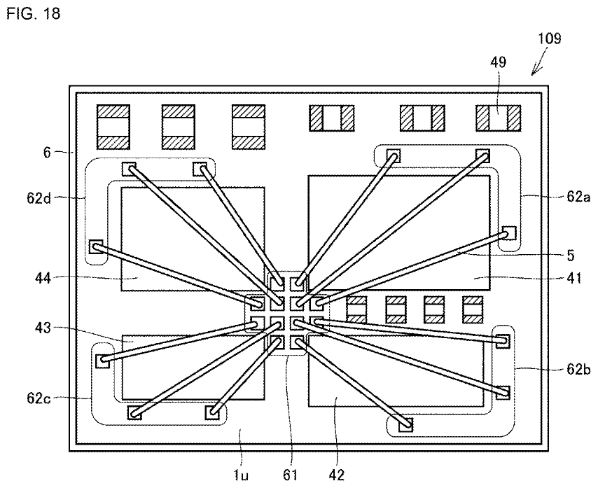

A module according to a sixth embodiment of the present disclosure will be described below with reference to FIG. 17 to FIG. 18. FIG. 17 illustrates a module 109 according to the present embodiment in perspective plan view. A region is clearly illustrated in FIG. 18.

In the module 109, four components are mounted on the main surface 1u of the substrate 1. That is, the first component 41, the second component 42, the third component 43 and the fourth component 44 are mounted on the main surface 1u. There is provided the common first region 61 in which the first ends 51 of the wires 5 with respect to these components are connected to the main surface 1u with concentration thereon, and the four components are arranged so as to contact the first region 61 at respective corner portions thereof. The second regions 62a, 62b, 62c and 62d are arranged along the sides of the respective components. The second regions 62a, 62b, 62c, and 62d correspond to the first component 41, the second component 42, the third component 43, and the fourth component 44, respectively.

### Operation/Effects

Also in this embodiment, the same effects as those in the fifth embodiment can be obtained.

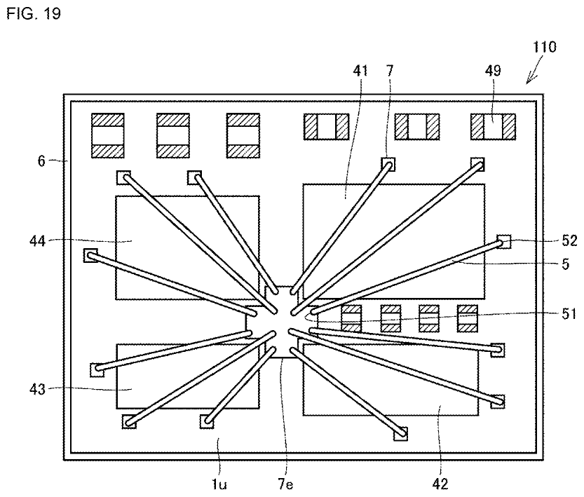

It should be noted that a configuration such as a module 110 illustrated in FIG. 19 may also be adopted. In the module 110, an integrating pad electrode 7e is arranged in the first region 61 instead of arraying individual pad electrodes. The first ends 51 of the plurality of wires 5 are connected to the pad electrode 7e.

In the above embodiments, the components are substantially rectangular as an example, but the shapes of the components are not limited to a rectangle, and other shapes may also be used.

In addition, two or more of the above embodiments may be combined as appropriate. It should be noted that the above described embodiments are illustrative in all respects and are not restrictive. The scope of the disclosure is indicated by the appended claims and is intended to cover all modifications within the meaning and range equivalent to the scope of the appended claims.

While embodiments of the disclosure have been described above, it is to be understood that variations and modifications will be apparent to those skilled in the art without necessarily departing from the scope and spirit of the disclosure. The scope of the disclosure, therefore, is to be determined solely by the following claims.

What is claimed is:

1. A module comprising:
a substrate having a main surface;
a first component mounted on the main surface; and
two or more wires, each having a first end and a second end bonded to the main surface so that each of the two or more wires straddles the first component,
wherein a distance between first ends of two wires of the two or more wires that are adjacent to each other is shorter than a distance between second ends of the two wires when viewed in a direction perpendicular to the main surface.

2. The module according to claim 1,
wherein the first ends of the two or more wires are lined up on a same side of the first component when viewed in the direction perpendicular to the main surface.

3. The module according to claim 1 including a second component mounted on the main surface,
wherein the main surface has a first region in which the first ends of the two or more wires and the main surface are connected, and
at least a part of the first region is located between the first component and the second component.

4. The module according to claim 3,
wherein an integrating pad electrode to which two or more of the first ends are connected is arranged in the first region.

5. The module according to claim 1, including a sealing resin configured to cover the first component and the two or more wires.

6. The module according to claim 1, including a shield film spaced apart from the main surface and configured to cover the first component and the two or more wires.

7. The module according to claim 6,
wherein at least one of the two or more wires is in contact with the shield film.

8. The module according to claim 1,
wherein the first component is surrounded by at least a part of an aggregate of the first ends and the second ends of the two or more wires.

9. The module according to claim 3, including a sealing resin configured to cover the first component, the second component and the two or more wires.

10. The module according to claim 1,
wherein the first component is a low noise amplifier.

11. A module comprising:
a substrate having a main surface; and
a plurality of components mounted on the main surface,
wherein two or more wires are bonded to the main surface so as to straddle at least one of the plurality of the components,
each of the two or more wires has a first end and a second end,
the main surface has a common first region in which first ends of the two or more wires for the plurality of components are connected to the main surface, and
a center-to-center distance between two of the first ends adjacent to each other in the first region is shorter than a center-to-center distance between the second ends adjacent to each other in a portion other than the first region.

12. The module according to claim 2, including a second component mounted on the main surface,
wherein the main surface has a first region in which the first ends of the two or more wires and the main surface are connected, and
at least a part of the first region is located between the first component and the second component.

13. The module according to claim 2, including a sealing resin configured to cover the first component and the two or more wires.

14. The module according to claim 3, including a sealing resin configured to cover the first component and the two or more wires.

15. The module according to claim 4, including a sealing resin configured to cover the first component and the two or more wires.

16. The module according to claim 2, including a shield film spaced apart from the main surface and configured to cover the first component and the two or more wires.

17. The module according to claim 3, including a shield film spaced apart from the main surface and configured to cover the first component and the two or more wires.

18. The module according to claim 4, including a shield film spaced apart from the main surface and configured to cover the first component and the two or more wires.

19. The module according to claim 5, including a shield film spaced apart from the main surface and configured to cover the first component and the two or more wires.
